(19) United States
(12) Patent Application Publication
(10) Pub. No.: US 2008/0253067 A1
(43) Pub. Date: Oct. 16, 2008

(54) Assemblable display device

(75) Inventors: Guan-De Liou, Taipei City (TW); Chia-Pine Huang, Keelung City (TW); Li-Li Lai, Taipei City (TW); Stephen Tsai, Sijhih City (TW)

Correspondence Address: BACON & THOMAS, PLLC, 625 SLATERS LANE, FOURTH FLOOR, ALEXANDRIA, VA, 22314-1176, US

(73) Assignee: Hannspree, Inc., Taipei City (TW)

(21) Appl. No.: 11/826,782

(22) Filed: Jul. 18, 2007

(30) Foreign Application Priority Data
Apr. 11, 2007 (TW) 096112663

(51) Int. Cl. H05K 5/03

(52) U.S. Cl. 361/679

(57) ABSTRACT

An assemblable display device includes a housing, which has a chamber, an opening, multiple recessed holes of same configuration, and a assembling hole in each recessed hole, a display module located in the chamber and the display screen thereof fitting the opening, and assemblable member is selectively and can be assemble or disassemble into any desired assembling holes by hand.

### BACKGROUND OF THE INVENTION

1. Field of the Invention

The present invention relates to a flat panel display and more specifically, to an assemblable display device.

2. Description of Related Art

For a commercial LCD TV (Liquid Crystal Display Television), the antenna, stand, speakers are attachable accessories and structures. When these attachable accessories and structures are assembled with the screen, the whole assembly will have a huge size. Conventionally, if an assemblable design is adopted, a complicated fastening structure between assemble parts is necessary, and the user needs to use supplementary mounting tool during installation. For example, a spanner or screwdriver is required when assembling the accessories such as stand or speakers to the TV screen. This assembling procedure wastes much labor and time, and the TV or the related parts may be scratched accidentally.

Further, the assembling holes on the screen body of a commercial LCD TV are specifically shaped jacks for different accessories of different functions. The number and locations of these assembling holes are predetermined. For example, the screen body of a LCD TV has one power jack, one antenna jack, and two audio jacks. These jacks are arranged in a row on the bottom side of the back shell.

Therefore, the design of a commercial LCD TV does not allow the user to select the installation position of the attached accessories subject to the interior decoration, i.e., the user cannot install the attached accessories in the TV in different positions as desired.

Therefore, it is desirable to provide an assemblable display device that eliminates the aforesaid drawback.

### SUMMARY OF THE INVENTION

The present invention has been accomplished under the circumstances in view. According to the present invention, the assemblable display device comprises a housing, a display module, and at least one assemblable member.

The housing comprises a chamber, an opening, a plurality of recessed holes that have a same configuration, and an assembling hole in each of the recessed holes.

The display module is located in the chamber inside the housing, comprising a display screen that fits at the opening of the housing. Each assemblable member is selectively and can be assemble or disassemble into one of the assembling holes by hand.

Based on the aforesaid arrangement, the user can easily connect or disconnect the accessories to the display device by hand without any tools.

Further, the user can selectively install the assemblable members in the housing at different locations subject to different purpose requirements.

Further, at least one of the assembling holes is a threaded assembling hole, and at least one assemblable member comprises a threaded screw for screwing into the threaded assembling hole. Further, the holes can be through holes, and each assemblable member has a plug for fitting into the through hole tightly. By means of this plug-in design, each assemblable member can easily be installed in the selected assembling hole by hand without any tools. This assembling procedure is simple. To disassemble the assemblable member, the user can easily unscrew the assemblable member in the associating assembling hole, or pull the assemblable member directly out of the associating assembling hole by hand.

Further, the recessed holes of the housing can be arranged in a 2-dimensional array, or to show a concentric circle pattern or any of a variety of other configurations for assembling purposes.

Further, each assemblable member can be a support member for supporting the display device in vertical, a carrying handle for enabling a person to carry the display device by hand, a hanger for hanging the display device on the wall or a support, or a suction cup for securing the display device to a flat surface by means of a suction force.

Further, the display module comprises a heat generating electronic device situated on the back of the display module and close to the ventilation holes, and the at least one assemblable member includes a perfume dispenser assembled in the assembling hole corresponding to the heat generating electronic device. During the operation of the display module, the heat generated by the heat generating electronic device heats the perfume dispenser, causing the perfume dispenser to disperse a fragrant smell.

Further, the display module comprises at least one power terminal corresponding to at least one of the assembling holes, and at least one assemblable member includes a power cable installed in one of the assembling holes of the housing corresponding to the at least one power terminal and electrically connected the associating power terminal to provide electric power to the display device.

Further, the display module comprises at least one signal terminal corresponding to at least one of the assembling holes, and at least one assemblable member includes an antenna installed in one of the assembling holes of the housing corresponding to the at least one signal terminal and electrically connected the associating signal terminal for receiving external signals and transmitting external signals to the display device.

Further, the display module comprises at least one audio terminal corresponding to at least one of the assembling holes, and at least one assemblable member includes a speaker plugged in one of the assembling hole corresponding to the at least one audio terminal and electrically connected to the associating audio terminal for output of the audio signal generated by the display device.

### BRIEF DESCRIPTION OF THE DRAWINGS

FIG. 1 is an exploded view of a housing for assemblable display device in accordance with the present invention.

FIG. 2 is an elevational view of an assemblable display device in accordance with a first embodiment of the present invention.

FIG. 3 is an elevational view of an assemblable display device in accordance with a second embodiment of the present invention.

FIG. 4 is an elevational view of an assemblable display device in accordance with a third embodiment of the present invention.

FIG. 5 is an elevational view of an assemblable display device in accordance with a fourth embodiment of the present invention.

FIG. 6 is an elevational view of an assemblable display device in accordance with a fifth embodiment of the present invention.

FIG. 7 is an elevational view of an assemblable display device in accordance with a sixth embodiment of the present invention.

FIG. 8 is an elevational view of an assemblable display device in accordance with a seventh embodiment of the present invention.

FIG. 9 is an elevational view of an assemblable display device in accordance with an eighth embodiment of the present invention.

FIG. 10 is an elevational view of an assemblable type display device in accordance with a ninth embodiment of the present invention.

### DETAILED DESCRIPTION OF THE PREFERRED EMBODIMENT

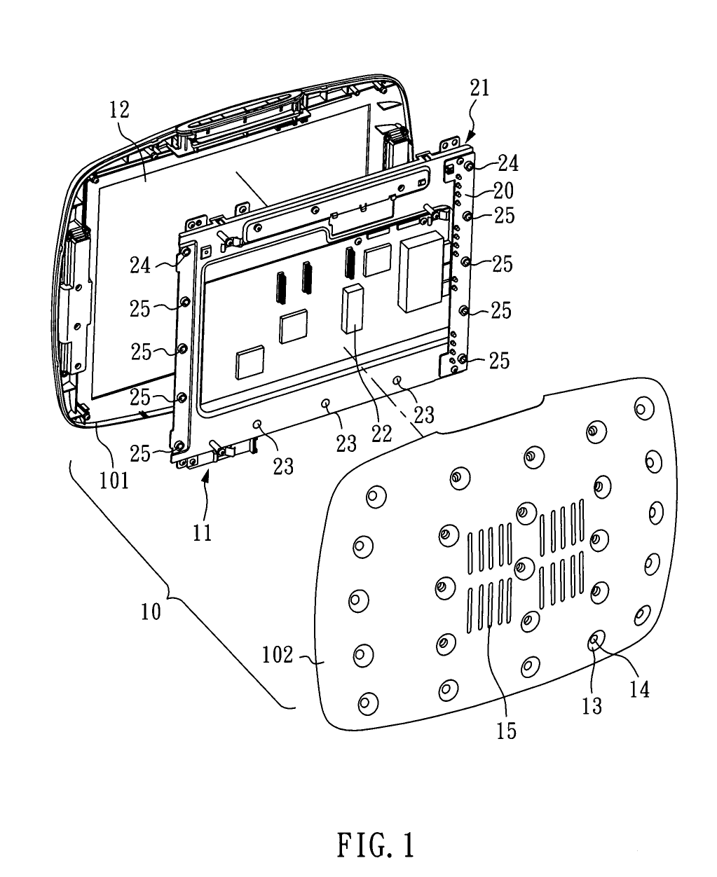

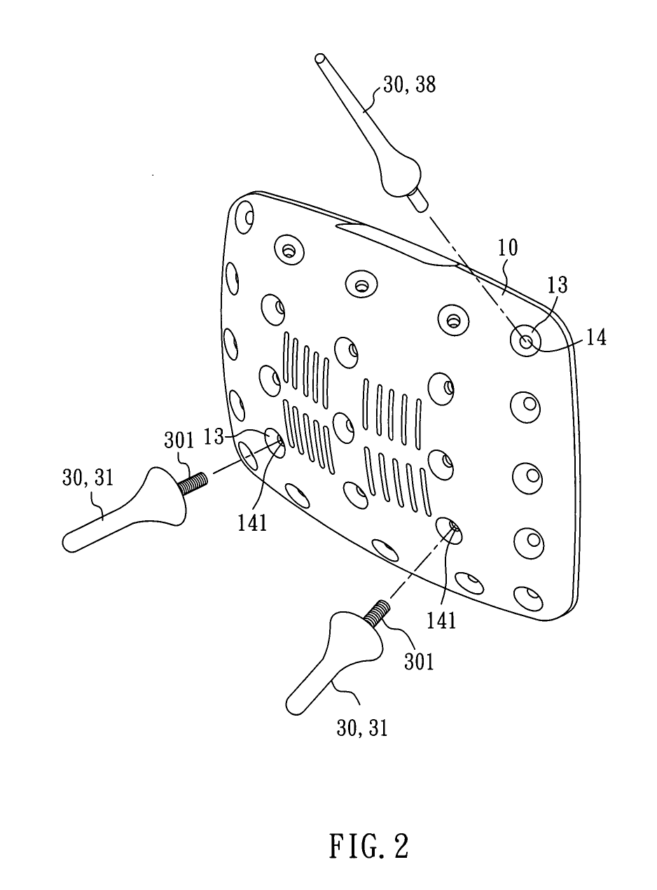

Referring to FIGS. 1 and 2, an assemblable display device in accordance with a first embodiment of the present invention is shown comprised of a housing 10, a display module 20, and three assemblable members 30. The housing 10 is formed of a front cover 101 and a rear cover 102. The housing 10 comprises a chamber 11, an opening 12, a plurality of ventilation holes 15, a plurality of recessed holes 13 having the same configuration, and an assembling hole 14 in each of the recessed holes 13.

Referring to FIG. 1, the display module 20 is located in the chamber 11 inside the housing 10, comprising a display screen 21, a heat generating electronic device 22, three power terminals 23, two signal terminals 24, and eight audio terminals 25. The display screen 21 of the display module 20 fits the opening 12 of the housing 10. The heat generating electronic device 22, power terminals 23, signal terminals 24 and audio terminals 25 of the display module 20 are disposed corresponding to the assembling holes 14 in the recessed holes 13 of the housing 10. According to this embodiment, the heat generating electronic device 22 is disposed at the center of the rear display module 20, the power terminals 23 are disposed at the bottom of the display module 20, the signal terminals 24 are bilaterally disposed at the top of the display module 20, the audio terminals 25 are respectively disposed at the left and right sides of the display module 20.

Referring to FIG. 2, the three assemblable members 30 include one antenna 38 and two support members 31. As shown in FIGS. 1 and 2, the antenna 38 is installed in one of the assembling holes 14 corresponding to the signal terminals 24, and adapted to receive an external signal and to transmit the signal to the display module 20. The two support members 31 are respectively fastened to two of the other assembling holes 14 for supporting the display device on a flat surface in a substantially vertical position. According to this embodiment, the connection between the antenna 38 and the associating assembling hole 14 is a direct plug-in design. The connection between each support member 31 and the associating assembling hole 14 is a screw design, i.e., the support member 31 has a threaded screw 301 at the one end, and the associating assembling hole 14 is a threaded screw hole 141 for receiving the threaded screw 301.

Based on the aforesaid arrangement, the user can conveniently assemble or disassemble the assemblable display device without any tools. Further, the user can freely install the assemblable members 30 in the housing 10 at selected locations.

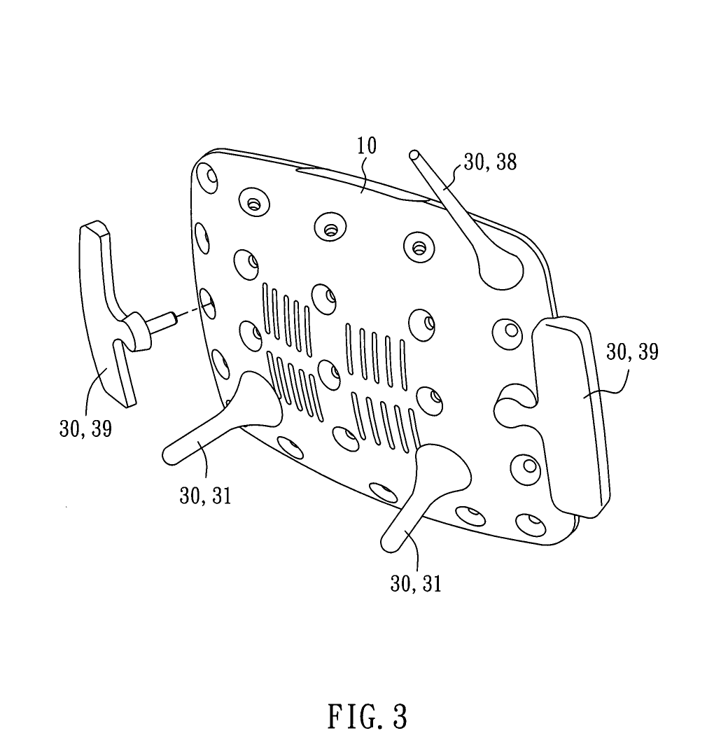

FIG. 3 is an elevational view of an assemblable display device in accordance with a second embodiment of the present invention. Please also refer to FIG. 1. This second embodiment is substantially similar to the aforesaid first embodiment with the exception of the two additional assemblable members 30, i.e., two additional speakers 39. The speakers 39 are respectively connected to two of the eight assembling holes 14 that are respectively situated at the eight audio terminals 25, and electrically connected to the associating audio terminals 25 for output of audio signal from the display module 20. According to this embodiment, the speakers 39 and the associating assembling holes 14 adopt a plug-in design, i.e., the speakers 39 are directly plugged into the associating assembling holes 14. This second embodiment has the same simple assemble and disassemble features.

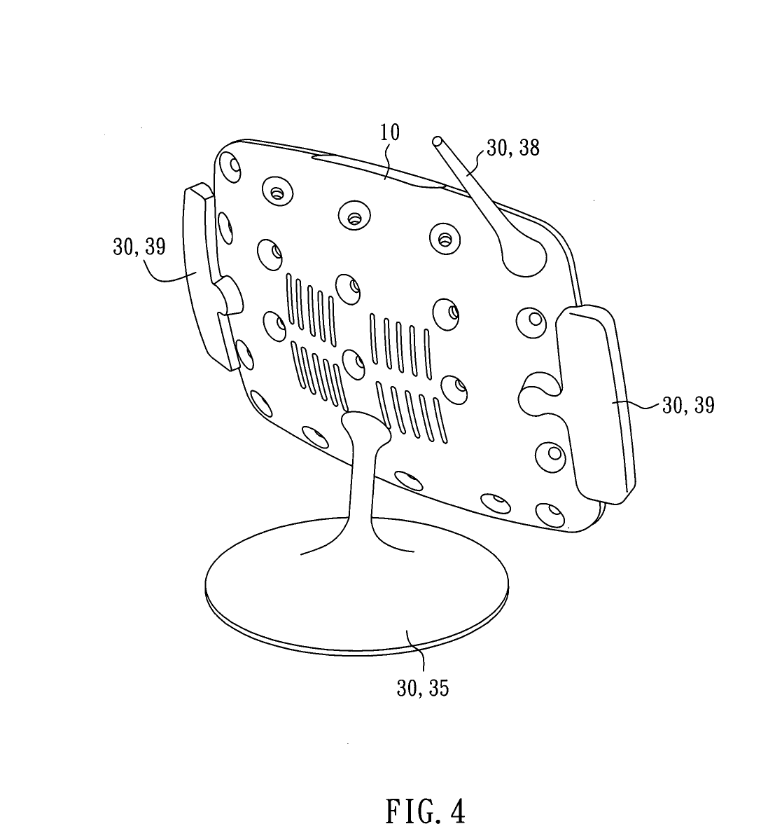

FIG. 4 is an elevational view of an assemblable display device in accordance with a third embodiment of the present invention. Please also refer to FIG. 1. This third embodiment is substantially similar to the aforesaid second embodiment with the exception of the use of a stand 35 to substitute for the use of two support members 31 in the aforesaid second embodiment for supporting the display device on a flat surface in a substantially vertical position. This third embodiment has the same simple assembling and disassembling features.

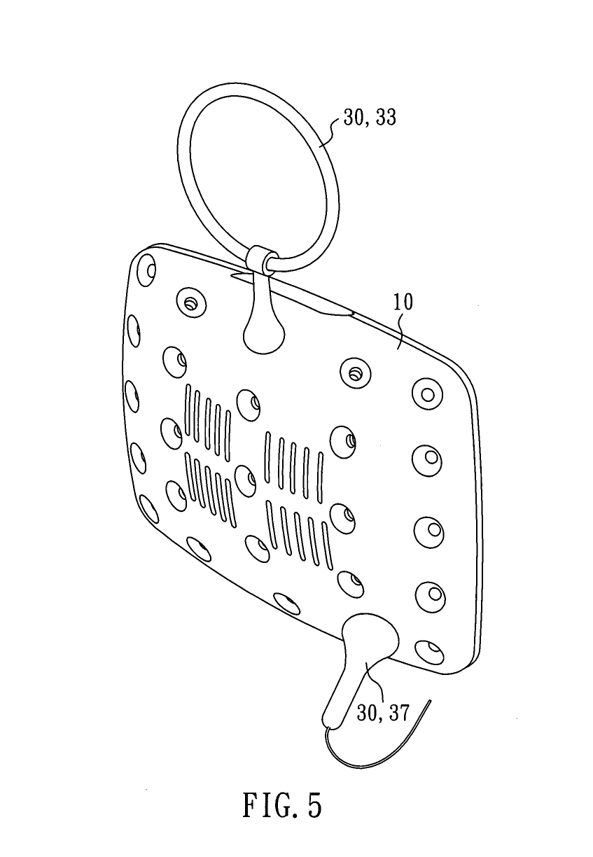

FIG. 5 is an elevational view of an assemblable display device in accordance with a fourth embodiment of the present invention. Please also refer to FIG. 1. This fourth embodiment is substantially similar to the aforesaid first embodiment with the exception that this fourth embodiment uses only two assemblable members 30, i.e., one hanger 33 for hanging the display device on the wall, and one power cable 37 installed in one of the three assemblable holes 14 corresponding to the three power terminals 23 and electrically connected to the associating power terminal 23. The power cable 37 is adapted to provide electric power to the display module 20.

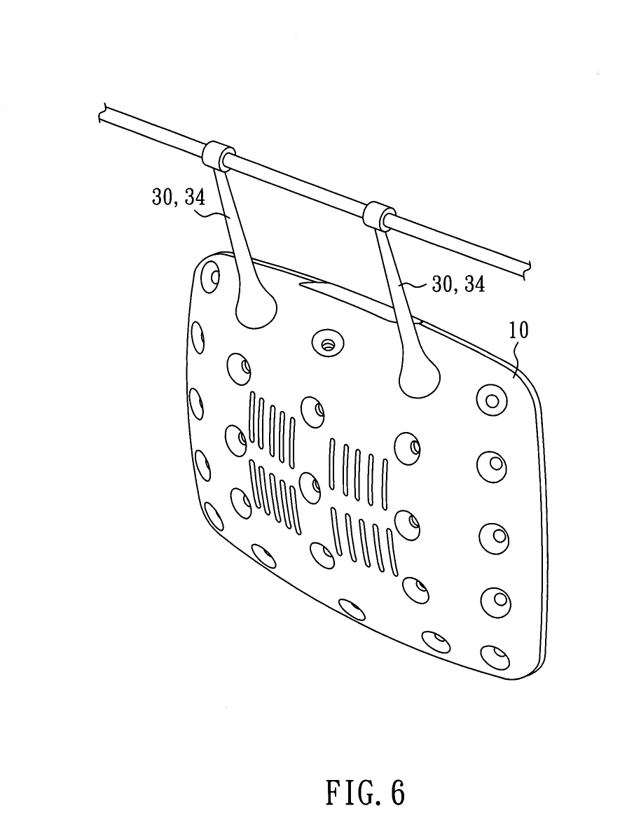

FIG. 6 is an elevational view of an assemblable display device in accordance with a fifth embodiment of the present invention. Please also refer to FIG. 1. This fifth embodiment is substantially similar to the aforesaid fourth embodiment with the exception that this fifth embodiment uses two assemblable members 30, i.e., two support arms 34 to substitute for the hanger 33 in the fourth embodiment for hanging the display device on a wall.

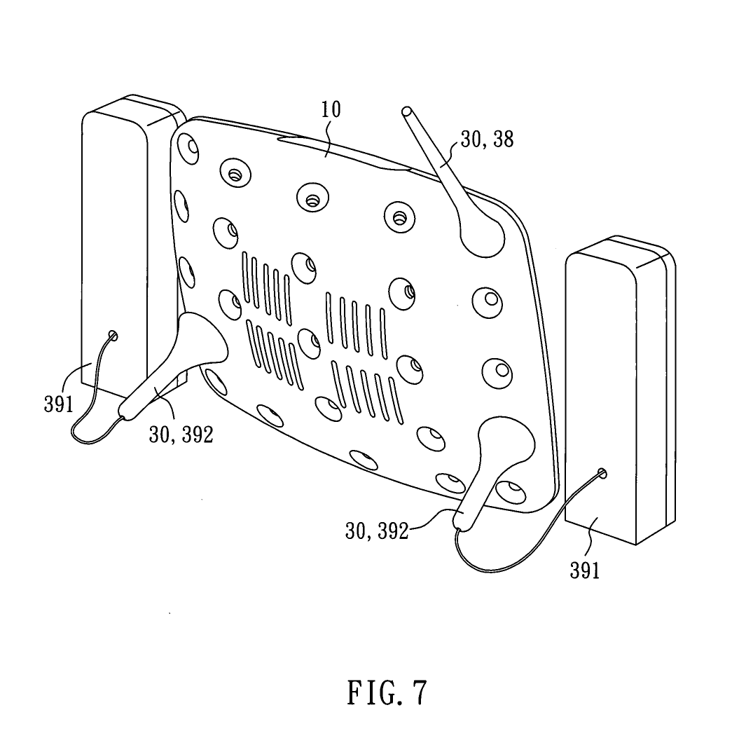

FIG. 7 is an elevational view of an assemblable display device in accordance with a sixth embodiment of the present invention. Please also refer to FIG. 1. This sixth embodiment is substantially similar to the aforesaid second embodiment with the exception that the assemblable members 30 include one antenna 38 and two speaker cables 392. The two speaker cables 392 are respectively connected to two of the eight assembling holes 14 that are respectively situated at the eight audio terminals 25, and electrically connect two external speakers 391 to the associating audio terminals 25 for output of audio signal from the display module 20, i.e., the speakers 391 and the assemblable display device are arranged in a separate unit manner. Like the aforesaid second embodiment, this sixth embodiment has the same simple assembling and disassembling features.

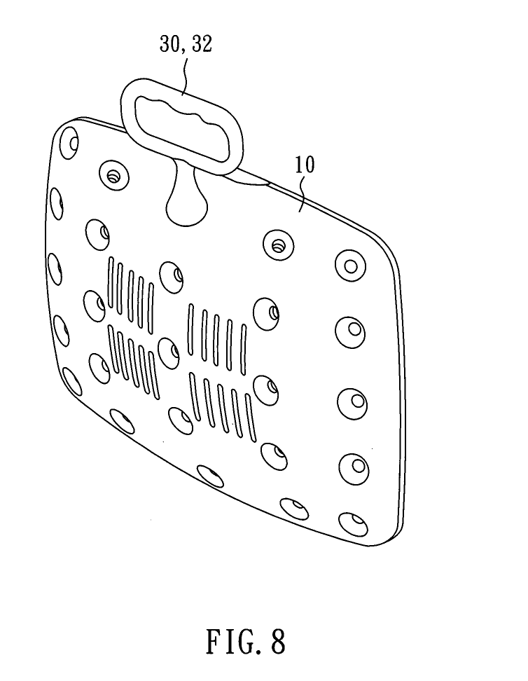

FIG. 8 is an elevational view of an assemblable display device in accordance with a seventh embodiment of the present invention. Please also refer to FIG. 1. This seventh embodiment is substantially similar to the aforesaid fourth embodiment with the exception that this seventh embodiment uses a carrying handle 32 as the assemblable member 30 to substitute for the hanger 33 of the aforesaid fourth embodiment. By means of the carrying handle 32, the user can carry the display device by hand.

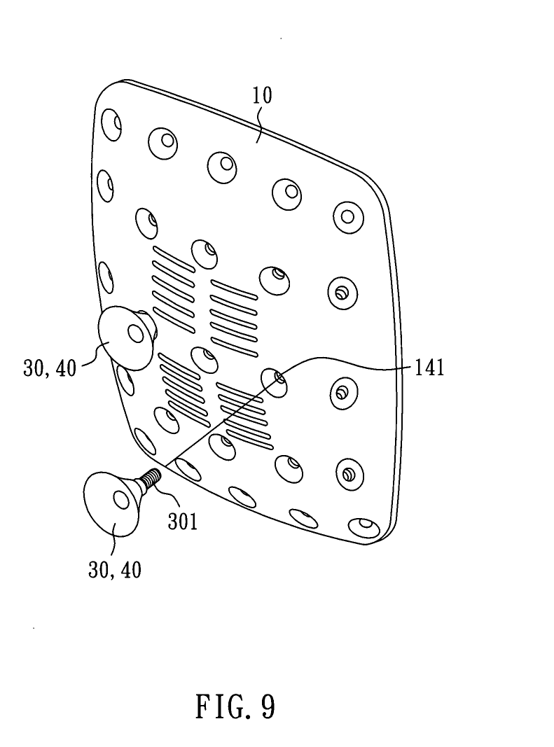

FIG. 9 is an elevational view of an assemblable display device in accordance with an eighth embodiment of the present invention. Please also refer to FIG. 1. This eighth embodiment is substantially similar to the aforesaid fourth embodiment with the exception that this seventh embodiment uses two mounting members 30, i.e., two suction cups 40 to substitute for the hanger 33 of the aforesaid fourth embodiment. By means of the suction cups 40, the display device can be clung to a flat glass or flat surface. According to this seventh embodiment, the display module 20 is held in vertical, i.e., perpendicular to the horizontal positioning of the display module 20 of the aforesaid fourth embodiment. However, this is not a limitation. The suction cups 40 may be selectively installed in the other assembling holes 14 of the housing 10 for different position or different angles of the display device.

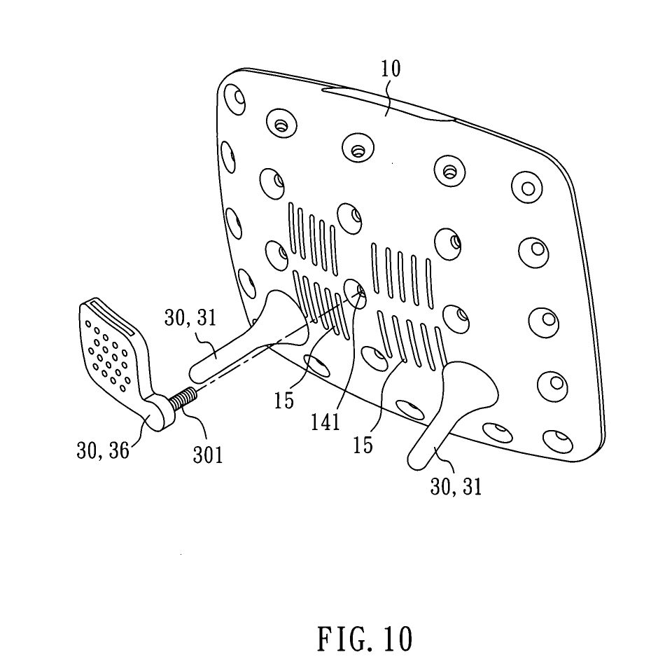

FIG. 10 is an elevational view of an assemblable display device in accordance with a ninth embodiment of the present invention. Please also refer to FIG. 1. This ninth embodiment is substantially similar to the aforesaid first embodiment with the exception that the three assemblable members 30 of this ninth embodiment include a perfume dispenser 36 and two support members 31. The perfume dispenser 36 is assembled in the threaded screw hole 141 corresponding to the heat generating electronic device 22 and near the ventilation holes 15. During the operation of the display module 20, the heat generated by the heat generating electronic device 22 is carried by air through the ventilation holes 15 to heat the perfume dispenser 36, causing the perfume dispenser 36 to release a fragrant smell. According to this embodiment, the perfume dispenser 36 has a threaded screw 301 and screwed into the threaded screw hole 141.

Although the present invention has been explained in relation to its preferred embodiments, it is to be understood that many other possible modifications and variations can be made without departing from the spirit and scope of the invention as hereinafter claimed.

What is claimed is:

1. An assemblable display device comprising:
a housing, said housing comprising a chamber, an opening, a plurality of recessed holes, and a assembling hole in each of said recessed holes;
a display module located in said chamber inside said housing, said display module comprising a display screen fitting said opening of said housing; and
at least one assemblable member selectively assemble in at least one of said assembling holes.

2. The assemblable display device as claimed in claim 1, wherein said assembling holes include at least one threaded assembling hole; said at least one assemblable member comprises at least one threaded screw for screwing into said at least one threaded assembling hole.

3. The assemblable display device as claimed in claim 1, wherein said recessed holes of said housing are arranged in a 2-dimensional array.

4. The assemblable display device as claimed in claim 1, wherein said at least one assemblable member includes a support member for supporting said assemblable display device.

5. The assemblable display device as claimed in claim 1, wherein said at least one assemblable member includes a carrying handle for enabling a person to carry said assemblable display device by hand.

6. The assemblable display device as claimed in claim 1, wherein said at least one assemblable member includes a hanger for hanging said assemblable display device on a support means.

7. The assemblable display device as claimed in claim 1, wherein said at least one assemblable member includes a suction cup for cling said assemblable display device on a flat surface.

8. The assemblable display device as claimed in claim 1, wherein said display module comprises a heat generating electronic device situated at one of said assembling holes; said at least one assemblable member includes a perfume dispenser assembled in the assembling hole corresponding to said heat generating electronic device.

9. The assemblable display device as claimed in claim 1, wherein said display module comprises at least one power terminal corresponding to at least one of said assembling holes; said at least one assemblable member includes a power cable connected to one of the assembling holes of said housing corresponding to said at least one power terminal and electrically connected the associating power terminal to provide electric power to said assemblable display device.

10. The assemblable display device as claimed in claim 1, wherein said display module comprises at least one signal terminal corresponding to at least one of said assembling holes; said at least one assemblable member includes an antenna connected to one of the assembling holes of said housing corresponding to said at least one signal terminal and electrically connected the associating signal terminal for receiving external signals and transmitting external signals to said assemblable display device.

11. The assemblable display device as claimed in claim 1, wherein said display module comprises at least one audio terminal corresponding to at least one of said assembling holes; said at least one assemblable member includes a speaker connected to one of the assembling hole corresponding to said at least one audio terminal and electrically connected to the associating audio terminal for output of an audio signal from said assemblable display device.
